(19) United States
(12) Patent Application Publication
(10) Pub. No.: US 2006/0125062 A1
(43) Pub. Date: Jun. 15, 2006

(54) Semiconductor package having improved adhesion and solderability

(76) Inventors: Edgar R. Zuniga-Ortiz, McKinney, TX (US); Sreenivasan K. Koduri, Plano, TX (US); Donald C. Abbott, Norton, MA (US)

Correspondence Address: TEXAS INSTRUMENTS INCORPORATED, P O BOX 655474, M/S 3999, DALLAS, TX, 75265, US

(21) Appl. No.: 11/015,692

(22) Filed: Dec. 15, 2004

(51) Int. Cl. H01L 23/495

(52) U.S. Cl. 257/666

(57) ABSTRACT

A leadframe with a base metal structure (for example, copper) and first and second surfaces. A first metal layer, which is adhesive to polymeric materials such as molding compounds, is adherent to the first leadframe surface. The second leadframe surface is covered by a second metal layer for affinity to reflow metals such as tin alloy; this second metal layer has a different composition from the first metal layer. One example of the first surface is a nickel layer (201) in contact with the base metal (105), a palladium layer (202) in contact with the nickel layer, and an outermost tin layer (203) in contact with the palladium. Another example is an oxidized surface of the base metal. The second metal layer, on the second leadframe surface, comprises a nickel layer (201) in contact with the base metal (105), a palladium layer (202) in contact with the nickel layer, and an outermost gold layer (204) in contact with the palladium layer.

### FIELD OF THE INVENTION

The present invention is related in general to the field of semiconductor devices and processes, and more specifically to the materials and fabrication of leadframes for integrated circuit devices and semiconductor components.

### DESCRIPTION OF THE RELATED ART

Leadframes for semiconductor devices provide a stable support pad for firmly positioning the semiconductor chip, usually an integrated circuit (IC) chip within a package. Since the leadframe, including the pad, is made of electrically conductive material, the pad may be biased, when needed, to any electrical potential required by the network involving the semiconductor device, especially the ground potential.

In addition, the leadframe offers a plurality of conductive segments to bring various electrical conductors into close proximity of the chip. The remaining gap between the inner end of the segments and the contact pads on the IC surface are bridged connectors, typically thin metallic wires individually bonded to the IC contact pads and the leadframe segments. Consequently, the surface of the inner segment ends has to be suitable for stitch-attaching the connectors.

Also, the ends of the lead segment remote from the IC chip (“outer” ends) need to be electrically and mechanically connected to external circuitry, for instance to assembly printed circuit boards. In the overwhelming majority of electronic applications, this attachment is performed by soldering, conventionally with lead-tin (Pb/Sn) eutectic solder at a reflow temperature in the 210 to 220° C. range. Consequently, the surface of the outer segment ends has to be affine to reflow metals or alloys.

Finally, the leadframe provides the framework for encapsulating the sensitive chip and fragile connecting wires. Encapsulation using plastic materials, rather than metal cans or ceramic, has been the preferred method because of low cost. The transfer molding process for epoxy-based thermoset compounds at 175° C. has been practiced for many years. The temperature of 175° C. for molding and mold curing (polymerization) is compatible with the temperature of 210 to 220° C. for eutectic solder reflow.

Reliability tests in moist environments require that the molding compound have good adhesion to the leadframe and the device parts it encapsulates. Two major contributors to good adhesion are the chemical affinity of the molding compound to the metal of the leadframe and the surface roughness of the leadframe.

The recent general trend to avoid Pb in the electronics industry and use Pb-free solders, pushes the reflow temperature range into the neighborhood of about 260° C. This higher reflow temperature range makes it more difficult to maintain the mold compound adhesion to the leadframes required to avoid device delamination during reliability testing at moisture levels. This is especially true for the very small leadframe surface available in QFN (Quad Flat No-lead) and SON (Small Outline No-lead) devices. For this temperature range, known leadframes do not offer metallization for good adhesion combined with low cost, easy manufacturability, and avoidance of whiskers.

It has been common practice to manufacture single piece leadframes from thin (about 120 to 250 μm) sheets of metal. For reasons of easy manufacturing, the commonly selected starting metals are copper, copper alloys, and iron-nickel alloys (for instance the so-called “Alloy 42”). The desired shape of the leadframe is etched or stamped from the original sheet. In this manner, an individual segment of the leadframe takes the form of a thin metallic strip with its particular geometric shape determined by the design. For most purposes, the length of a typical segment is considerably longer than its width.

### SUMMARY OF THE INVENTION

A need has therefore arisen for a low cost, reliable leadframe combining adhesion to molding compounds, bondability for connecting wires, solderability of the exposed leadframe segments, and no risk of tin dendrite growth. There are technical advantages, when the leadframe and its method of fabrication is low cost and flexible enough to be applied for different semiconductor product families and a wide spectrum of design and assembly variations, and achieves improvements toward the goals of improved process yields and device reliability. There are further technical advantages, when these innovations are accomplished using the installed equipment base so that no investment in new manufacturing machines is needed.

One embodiment of the present invention is a leadframe with a base metal structure and first and second surfaces; examples of the base metal are copper and iron-nickel alloy. A first metal layer, which is adhesive to polymeric materials such as molding compounds, is adherent to the first leadframe surface. The second leadframe surface is covered by a second metal layer for affinity to reflow metals such as tin alloy; this second metal layer has a different composition from the first metal layer.

The second metal layer, on the second leadframe surface, comprises a nickel layer in contact with the base metal, a palladium layer in contact with the nickel layer, and an outermost gold layer in contact with the palladium layer. For the first metal layer on the first leadframe surface a number of embodiments.

The first metal layer may comprise a nickel layer in contact with the base metal, a palladium layer in contact with the nickel layer, and an outermost tin layer in contact with the palladium. Or it may comprise a nickel layer in contact with the base metal, a palladium layer in contact with the nickel layer, a gold layer in contact with the palladium, and an outermost tin layer in contact with the gold layer. Or it may comprise a layer of silver, or, alternatively, a layer of silver on selected areas. Or it may comprise an oxidized first surface to form an oxide layer of the base metal adhesive to polymeric materials.

Another embodiment of the invention is a semiconductor device, which has a leadframe with a base metal and first and second surfaces, a chip mount pad and a plurality of lead segments. Each segment has a first end near the mount pad and a second end remote from the mount pad.

A first metal layer, adhesive to polymeric materials, is adherent to the first leadframe surface. The second leadframe surface is covered by a second metal layer for affinity to reflow metals. The second metal layer has a different composition from the first metal layer. A semiconductor chip is attached to the mount pad, and bonding wires interconnect the chip and the first ends of the lead segments. Polymeric encapsulation material covers the chip, the bonding wires and the first ends of the lead segments.

Another embodiment of the invention is a semiconductor device, which has a leadframe with a base metal and first and second surfaces, a chip mount pad and a plurality of lead segments. Each segment has a first end near the mount pad and a second end remote from the mount pad. The first leadframe surface is oxidized to form an oxide layer of the base metal adhesive to polymeric materials; selected areas of the first surface are covered by a silver metal. The second leadframe surface is covered by a metal layer for affinity to reflow metals. A semiconductor chip is attached to the mount pad, and bonding wires interconnect the chip and the first ends of the lead segments. Polymeric encapsulation material covers the chip, the bonding wires and the first ends of the lead segments.

The invention is particularly advantageous for the leadframes in QFN (Quad Flat No-leads) and SON (Small Outline No-leads) packages.

Another embodiment of the invention is a method for fabricating a leadframe, wherein a base metal structure with first and second surfaces is provided. Examples for the base metal are copper and iron-nickel alloy. The first surface is metallurgically prepared so that it becomes adhesive to polymeric material; the second surface is prepared so that it is affine to reflow metals.

The method offers several embodiments of metallurgical surface preparation. In one embodiment, the metallurgical preparation comprises the steps of plating on the first and second surfaces consecutively a layer of nickel on the base metal and a layer of palladium on the nickel layer. Then, plating on the first surface a layer of tin on the palladium layer; and plating on the second surface a layer of gold on the palladium layer.

In another embodiment, the first and second surfaces are consecutively plated with a layer of nickel on the base metal, a layer of palladium on the nickel layer, and a layer of gold on the palladium layer. Then, on the first surface, a layer of tin is plated on the gold layer.

In another embodiment, the first surface is selectively plated with a silver layer on the base metal, and the second surface is plated with a nickel layer on the base metal, a palladium layer on the nickel layer, and a gold layer on the palladium layer.

In another embodiment, the base metal is oxidized on the first surface, by unaided or by stimulated metal oxide growth, and a silver layer is plated on selected areas of the base metal oxide. On the second surface, there is a nickel layer plated on the base metal, a palladium layer plated on the nickel layer, and a gold layer plated on the palladium layer.

Another embodiment of the invention is a method for completing the fabrication of an assembled and encapsulated semiconductor device. Exposed base metal portions of the second surface of a leadframe are plated consecutively with a nickel layer on the base metal, a palladium layer on the nickel layer, and a gold layer on the palladium layer.

It belongs to the technical advantages of the invention that no toxic or whiskering materials are used for the plating steps, down-bonding capability is enhanced, and moisture-level quality is improved. Furthermore, the required plating processes are inexpensive and easy to manufacture; for most embodiments, no post-mold plating is required.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 is a schematic cross section of the base metal structure of a portion of a leadframe strip having formed leadframe structures.

FIGS. 2 to 5 illustrate schematic cross sections of leadframe strip portions with a base metal structure and first and second surfaces, after the first surface has metallurgically been prepared for adhesion to polymeric materials, and its second surface has metallurgically been prepared for affinity to reflow metals, according to various embodiments of the invention.

FIG. 2 depicts one embodiment of the invention.

FIG. 3 depicts another embodiment of the invention.

FIG. 4 depicts another embodiment of the invention.

FIG. 5 depicts another embodiment of the invention.

FIG. 6 shows a schematic cross section of a portion of a leadframe strip, prepared according to an embodiment of the invention, after a plurality of semiconductor chips have been assembled and encapsulated on one leadframe surface.

FIG. 7 shows a schematic cross section of a saw-singulated semiconductor device of the QFN type, using a leadframe fabricated according to an embodiment of the invention.

FIG. 8 is a schematic top view of a typical leadframe strip with a plurality of encapsulated QFN-type semiconductor devices before singulation.

### DETAILED DESCRIPTION OF THE PREFERRED EMBODIMENTS

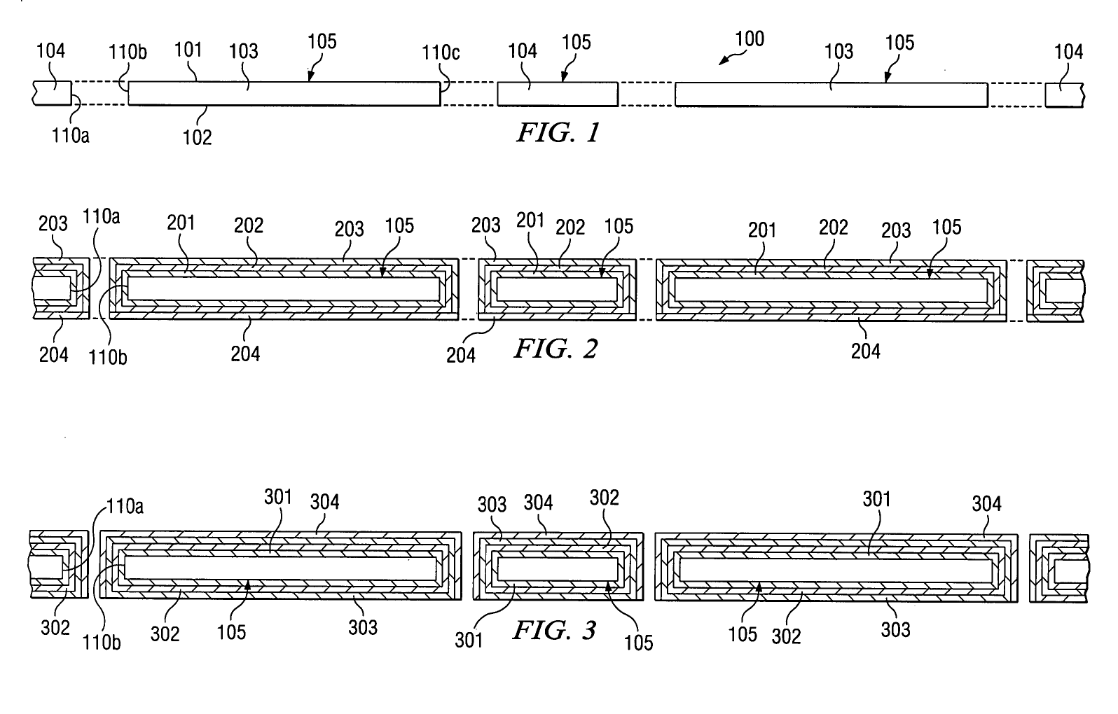

FIG. 1 is a schematic and simplified cross section of the starting material of a leadframe portion, generally designated 100. The leadframe has a first surface 101 and a second surface 102. The portion depicted contains a plurality of chip mount pads 103 and a plurality of lead segments 104. The leadframe is made of a base metal 105.

As defined herein, the starting material of the leadframe is called the “base metal”, indicating the type of metal. Consequently, the term “base metal” is not to be construed in an electrochemical sense (as in opposition to ‘noble metal’) or in a structural sense.

Base metal 105 is typically copper or a copper alloy. Other choices comprise brass, aluminum, iron-nickel alloys (“Alloy 42”), and covar.

Base metal 105 originates with a metal sheet in the preferred thickness range from 100 to 300 μm; thinner sheets are possible. The ductility in this thickness range provides the 5 to 15% elongation that facilitates the segment bending and forming operation of the finished device. The leadframe parts such as chip mount pads, lead segments, connecting rails (not shown in FIG. 1, but hinted at by dashed lines) are stamped or etched from the starting metal sheet. These stamping or etching processes create numerous side edges 110a, 110b, 110c, etc. of the leadframe parts.

FIGS. 2, 3 and 4 are schematic cross sections of the leadframe 100 to illustrate various embodiments of the inventions, which prepare the first surface 101 metallurgically for adhesion to polymeric materials, and the second surface 102 metallurgically for affinity to reflow metals. In these embodiments, the metallurgical preparations include at least one adherent layer of metal, preferably deposited by plating; in the cases of more than one metal, the adherent layers are often referred to as a stack.

In FIG. 2, a nickel layer 201 is in contact with the base metal 105. Nickel layer 201 covers the first and second leadframe surfaces as well as the side edges 110a, 110b, etc.; the preferred thickness range of the nickel layer is between about 0.5 and 2.0 μm. In contact with the nickel layer 201 is a palladium layer 202. The palladium layer covers also the first and second surfaces as well as the side edges. The preferred thickness range of the palladium layer 202 is between about 0.005 and 0.15 μm.

With the second surface protected by a mask, the first surface and the side edges are then plated with a thin layer 203 of tin; the thickness of this tin flash is preferably less than 5 nm. The thin tin enhances the adhesion to polymeric materials such as encapsulants made primarily of polyimide or epoxy, and molding compounds; data indicate that the adhesion is improved about ten times compared to the conventionally used gold. However, the tin has no potential for growing whiskers because of its thinness.

In a reverse protection step, the first leadframe surface is masked and the exposed second surface is plated with a thin layer 204 of gold in contact with the underlying palladium. The preferred thickness range of the gold layer is between about 3 and 15 nm. The second leadframe surface is thus plated with a stack of nickel layer in contact with the base metal, palladium layer, and outermost gold layer; in total, it has good affinity to reflow metals (examples of reflow metals include tin, tin alloys including tin/silver, tin/indium, tin/bismuth, tin/lead, tin/copper, tin/silver/copper, and indium).

The schematic cross section of FIG. 3 illustrates another embodiment of the invention. Similar to FIG. 2, a nickel layer 301 is in contact with the base metal 105. Nickel layer 301 covers the first and second leadframe surfaces as well as the side edges 110a, 110b, etc.; the preferred thickness range of the nickel layer is between about 0.5 and 2.0 μm. In contact with the nickel layer 301 is a palladium layer 302. The palladium layer covers also the first and second surfaces as well as the side edges. The preferred thickness range of the palladium layer 302 is between about 0.005 and 0.15 μm. In contact with the palladium layer 302 is a gold layer 303; it is plated in a thickness between about 3 to 15 nm.

With the second leadframe surface masked, the first surface and the side edges are then selectively plated with a thin layer of tin; the thickness of this tin layer 304 is preferably less than 5 nm. At this thinness, the tin layer has no potential for growing whiskers.

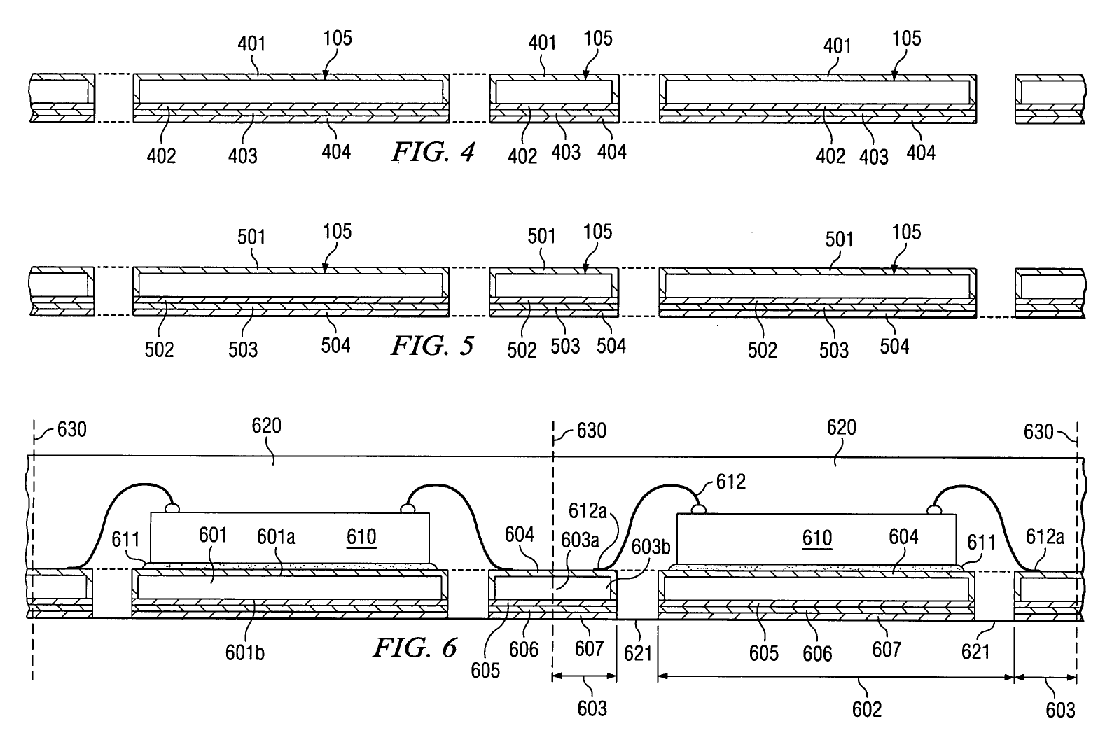

The schematic cross section of FIG. 4 illustrates another embodiment of the invention. The first surface of base metal 105 as well as the side edges of the leadframe structure are plated with a silver layer 401 preferably in the thickness range from about 2 to 5 μm. Silver provides very good adhesion to molding compounds and other polymeric encapsulants; it is also well known to facilitate stitch and wedge bonding in wire and ribbon bonding technologies. Alternatively, the silver may be plated in selected areas of the first surface (so-called silver spots).

With the first leadframe surface protected, the second surface is plated with a nickel layer 402 in contact with base metal 105; the thickness of the nickel layer is preferably in the 0.5 to 2.0 μm range. In contact with the nickel layer 402 is a palladium layer 403; the preferred thickness range of the palladium layer 403 is between about 0.005 and 0.15 μm. In contact with the palladium layer 403 is a gold layer 404; it is preferably plated in a thickness between about 3 to 15 nm.

In another embodiment of the invention, schematically depicted in FIG. 5, the first surface of the base metal structure is oxidized to form an oxide layer of the base metal adhesive to polymeric materials. The oxidization can simply be achieved by unaided metal oxide growth, such as by exposure to ambient, or it can be stimulated, for instance by an exposure to an oxygen atmosphere or an oxygen plasma. When the base metal is copper, it is well known that copper oxide adheres well to molding compound and polymer encapsulants. Selective areas of the oxidized first surface are covered by a silver layer to facilitate wire stitch bonding.

With the first leadframe surface protected, the second surface is plated with a nickel layer 502 in contact with base metal 105; the thickness of the nickel layer is preferably in the 0.5 to 2.0 μm range. In contact with the nickel layer 502 is a palladium layer 503; the preferred thickness range of the palladium layer 503 is between about 0.005 and 0.15 μm. In contact with the palladium layer 503 is a gold layer 504; it is preferably plated in a thickness between about 3 to 15 nm.

In terms of ease and cost of leadframe manufacturing, the embodiment of FIG. 5 represents a preferred way to achieve good adhesion to molding compounds on one leadframe surface and good solderability with reflow metals on the opposite leadframe surface.

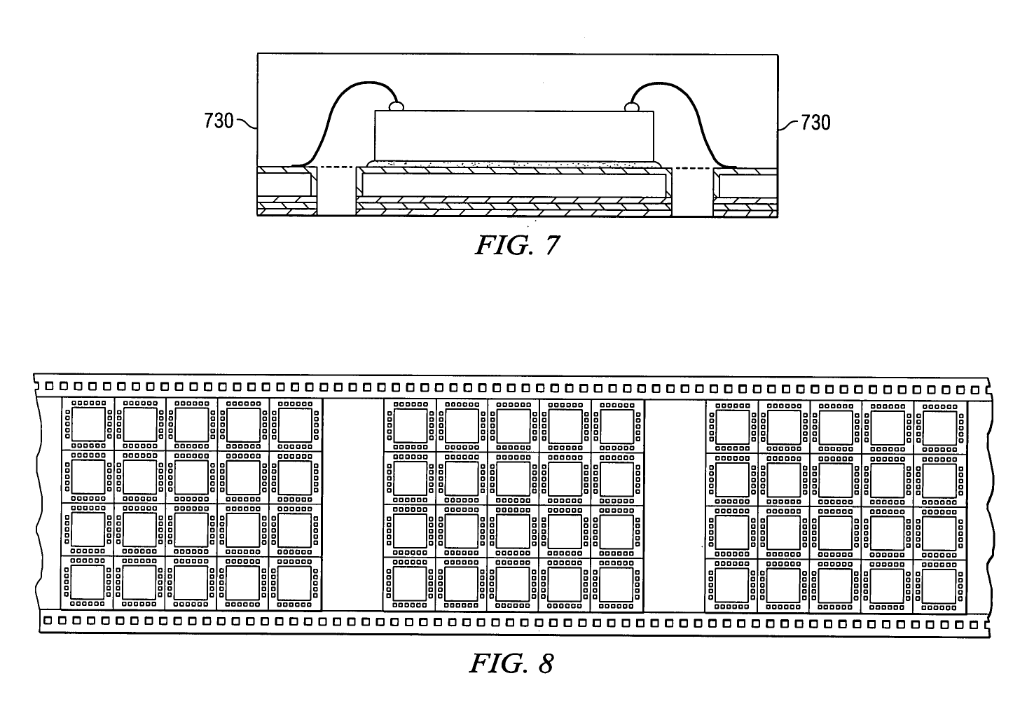

Another embodiment of the invention is a semiconductor device, as exemplified by the Quad Flat No-leads (QFN) or Small Outline No-leads (SON) device in FIG. 6. Actually, FIG. 6 shows a leadframe strip with a plurality of devices before singulation, and FIG. 7 shows one of these devices after singulation; FIG. 8 shows a top view of a leadframe strip with a plurality of devices before singulation. In the embodiment of the invention, the device has a leadframe with a base metal 601 and a first surface 601a and a second surface 601b. An example for the base metal is copper. Furthermore, the leadframe is structured into a chip mount pad 602 and a plurality of lead segments 603. Each lead segment has a first end 603a near chip mount pad 602, and a second end 603b remote from mount pad 602.

A first metal layer, adhesive to polymeric materials, is adherent to first leadframe surface 601a and the leadframe side edges. Out of the plurality of embodiments described above for the first leadframe surface, a surface layer 604 is chosen for FIG. 7, which calls for a silver. Alternatively, an oxidized layer of the base metal could have been chosen. Or, alternatively, a stack of layers could have been chosen: A nickel layer in contact with the base metal, a palladium layer in contact with the nickel layer, and an outermost tin layer in contact with the palladium layer. Or, a nickel layer in contact with the base metal, a palladium layer in contact with the nickel layer, a gold layer in contact with the palladium layer, and an outermost tin layer in contact with the gold layer.

The second leadframe surface 601b is covered by a second metal layer for affinity to reflow metals. Surface 601b is covered by an adherent stack of layers: Layer 605 is made of nickel and is in contact with base metal 601; layer 606 is made of palladium and is in contact with the nickel layer; and the outermost layer 607 is made of gold and is in contact with the palladium layer.

A semiconductor chip 610, for example an integrated circuit chip, is attached by means of an adhesive layer 611 to chip mount pad 602. Bonding wires 612 interconnect chip 610 with the first ends 603a of the lead segments 603. In some devices, selective silver areas 612a support the stitch attachments of wires 612. Polymeric encapsulation material 620, for example molding compound, covers chip 610, bonding wires 612 and first ends 603a of the lead segments. The polymeric material 620 also fills the gaps between chip 610 and the first ends of the lead segments and thus covers the leadframe side edges. Consequently, polymeric material 620 also forms a surface 621 in the same plane as the outermost surface layer 607. Reflow metals may cover some portions, or all, of the second leadframe surface. As an example, a tin alloy may cover at least the second ends of the lead segments, or alternatively all of the lead segments and the exposed outer chip pad surface.

Dashed lines 630 indicate in FIG. 6 where a saw will cut the completed leadframe strip into individual devices. The saw is cutting through encapsulation material 620 as well as through the leadframe segments. A singulated device is illustrated in FIG. 7, exhibiting straight sides 730 created by the sawing process.

Another embodiment of the invention is a method for fabricating a leadframe, which comprises the steps of providing a base metal structure with first and second surfaces, followed by the step of preparing the first surface metallurgically so that it adheres to polymeric materials, and the second surface metallurgically so that it is affine to reflow metals. Dependent on the leadframe to be fabricated, the invention provides a plurality of process step options for the metallurgical preparation:

Plating consecutively on the first and second surfaces a layer of nickel on the base metal and a layer of palladium on the nickel layer; plating then on the first surface a layer of tin on the palladium layer; and plating finally, on the second surface, a layer of gold on the palladium layer.

Plating consecutively on the first and second surfaces a layer of nickel on the base metal, a layer of palladium on the nickel layer, and a layer of gold on the palladium layer; and plating then, on the first surface, a layer of tin on the gold layer.

Plating on the first surface of the base metal a layer of silver; and plating then on the second surface of the base metal a layer of nickel, followed by a layer of palladium on the nickel layer, and finally a layer of gold on the palladium layer.

Oxidizing the base metal on the first surface, employing either an unaided metal oxide growth procedure, or by a stimulated metal oxide growth technique; and plating on the second surface consecutively a layer of nickel on the base metal, a layer of palladium on the nickel layer, and a layer of gold on the palladium layer.

Another embodiment of the invention is a method for completing the fabrication of a semiconductor device. The method comprises the following steps:

Providing a leadframe strip, which has a base metal and first and second surfaces; the first surface has a plurality of assembled and encapsulated chips, while at least portions of the second surface are exposing the base metal. In the next step, these exposed portions of the second surface are plated with a layer of nickel on the base metal, a layer of palladium on the nickel layer, and a layer of gold on the palladium layer. The method is usually concluded by the step of cutting the leadframe strip so that each leadframe unit has one encapsulated chip, whereby the completed devices are singulated.

This latter method is often referred to as post-mold plating, since the chips are already encapsulated at the beginning of the method. For the present invention, the first leadframe surface has been metallurgically prepared for adhesion to polymeric materials before the chips are assembled and encapsulated by employing one of the afore-described methods.

Whenever the methods described above require a selective metal deposition of a layer onto the leadframe, an inexpensive, temporary masking step is used, which leaves only those leadframe portions exposed which are intended to receive the metal layer. Because of the fast plating time, conventional selective spot plating techniques can be considered, especially reusable rubber masks. For thin metal plating, a wheel system is preferred as described below.

There are several methods to selectively deposit metals from solution onto a continuous strip. For high volume production of leadframes, continuous strip or reel-to-reel plating is advantageous and common practice. For applications where loose tolerances are acceptable for the boundaries of the metal layer plating on the inner ends of the lead segments, the preferred deposition method for the present invention is the so-called “wheel system”.

In the wheel system, material is moved over a large diameter wheel with apertures in it to allow solution flow to material. These apertures define the locations for plating and index pins engage the pilot holes in the leadframe. A backing belt is used to hold material on the wheel and a mask on the backside of the material. The anode is stationary inside the wheel. Among the advantages of the wheel system is a fast operating speed, since the material never stops for selective plating. There are no timing issues, and the pumps, rectifiers, and drive system are on continuously. The wheel system is low cost because the system is mechanically uncomplicated. However, the boundaries of plated layers are only loosely defined. A more precise, but also more costly and slower selective plating technique is the step-and-repeat process.

In the step-and-repeat system, the leadframe material is stopped in selective plating heads. A rubber mask system clamps on the material-to-be-plated. A plating solution is jetted at the material. Electrical current is applied and shut off after a pre-determined period of time. Then, the solution is shut off and the head opens. Thereafter, the material moves on. Among the advantages of the step-and-repeat system are a very sharp plating spot definition with excellent edges, further a very good spot location capability when used with index holes, pins and feedback vision system.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to products using any type of semiconductor chip, discrete or integrated circuit, and the material of the semiconductor chip may comprise silicon, silicon germanium, gallium arsenide, or any other semiconductor or compound material used in IC manufacturing.

As another example, the process step of stamping the leadframes from a sheet of base metal may be followed by a process step of selective etching, especially of the exposed base metal surfaces in order to create large-area contoured surfaces for improved adhesion to molding compounds.

It is therefore intended that the appended claims encompass any such modifications or embodiment.

We claim:

1. A leadframe comprising:
a base metal structure having first and second surfaces;
a first metal layer, adhesive to polymeric materials, adherent to said first surface; and
said second surface covered by a second metal layer for affinity to reflow metals, said second metal layer having a different composition from said first metal layer.

2. The leadframe according to claim 1 wherein said base metal is selected from a group consisting of copper, copper alloy, aluminum, iron-nickel alloy, and covar.

3. The leadframe according to claim 1 wherein said first metal layer comprises a nickel layer in contact with said base metal, a palladium layer in contact with said nickel layer, and an outermost tin layer in contact with said palladium layer.

4. The leadframe according to claim 1 wherein said first metal layer comprises a nickel layer in contact with said base metal, a palladium layer in contact with said nickel layer, a gold layer in contact with said palladium layer, and an outermost tin layer in contact with said gold layer.

5. The leadframe according to claim 1 wherein said first metal layer comprises a silver layer in contact with said base metal.

6. The leadframe according to claim 1 wherein said second metal layer comprises a nickel layer in contact with said base metal, a palladium layer in contact with said nickel layer, and an outermost gold layer in contact with said palladium layer.

7. A leadframe comprising:
a base metal structure having first and second surfaces;
said first surface oxidized to form an oxide layer of said base metal adhesive to polymeric materials; and
said a metal layer covering said second surface having affinity to reflow metals.

8. The leadframe according to claim 7 in which a silver layer covers selective areas on said first surface.

9. The leadframe according to claim 7 wherein said metal layer on said second surface comprises a nickel layer in contact with said base metal, a palladium layer in contact with said nickel layer, and an outermost gold layer in contact with said palladium layer.

10. A semiconductor device comprising:
a leadframe of a base metal with a first and second surface, a chip mount pad and a plurality of lead segments, each segment having a first end near said mount pad and a second end remote from said mount pad;
a first metal layer, adhesive to polymeric materials, adherent to said first surface; and said second surface covered by a second metal layer for affinity to reflow metals, said second metal layer having a different composition from said first metal layer;
a semiconductor chip attached to said mount pad;
bonding wires interconnecting said chip and said first ends of said lead segments; and
polymeric encapsulation material covering said chip, said bonding wires and said first ends of said lead segments.

11. The device according to claim 10 further comprising reflow metals on said second leadframe surface, selectively covering at least said second ends of said lead segments.

12. The device according to claim 10 wherein said leadframe is for QFN (Quad Flat No-leads) or for SON (Small Outline No-leads) packages.

13. The device according to claim 10 wherein said first metal layer comprises a nickel layer in contact with said base metal, a palladium layer in contact with said nickel layer, and an outermost tin layer in contact with said palladium layer.

14. The device according to claim 10 wherein said first metal layer comprises a nickel layer in contact with said base metal, a palladium layer in contact with said nickel layer, a gold layer in contact with said palladium layer, and an outermost tin layer in contact with said gold layer.

15. The device according to claim 10 wherein said first metal layer comprises a silver layer in contact with said base metal.

16. The device according to claim 10 wherein said second metal layer comprises a nickel layer in contact with said base metal, a palladium layer in contact with said nickel layer, and an outermost gold layer in contact with said palladium layer.

17. A semiconductor device comprising:
a leadframe of a base metal with a first and second surface, a chip mount pad and a plurality of lead segments, each segment having a first end near said mount pad and a second end remote from said mount pad;
said first surface oxidized to form an oxide layer of said base metal adhesive to polymeric materials with selective areas covered by a silver layer; and said second surface covered by a metal layer for affinity to reflow metals;
a semiconductor chip attached to said mount pad;
bonding wires interconnecting said chip and said first ends of said lead segments; and
polymeric encapsulation material covering said chip, said bonding wires and said first ends of said lead segments.

18. A method for fabricating a leadframe comprising the steps of:
providing a base metal structure having first and second surfaces;
preparing said first surface metallurgically so that it becomes adhesive to polymeric materials; and
preparing said second surface metallurgically so that so that it becomes affine to reflow metals.

19. The method according to claim 18 wherein said structure is suitable as a semiconductor device leadframe.

20. The method according to claim 18 wherein said metallurgical preparation comprises the steps of:
plating on said first and second surfaces consecutively a layer of nickel on said base metal and a layer of palladium on said nickel layer;
plating on said first surface a layer of tin on said palladium layer; and
plating on said second surface a layer of gold on said palladium layer.

21. The method according to claim 18 wherein said metallurgical preparation comprises the steps of:
plating on said first and second surfaces consecutively a layer of nickel on said base metal, a layer of palladium on said nickel layer, and a layer of gold on said palladium layer; and
plating on said first surface a layer of tin on said gold layer.

22. The method according to claim 18 wherein said metallurgical preparation comprises the steps of:
plating on said first surface selectively a layer of silver on said base metal; and
plating on said second surface consecutively a layer of nickel on said base metal, a layer of palladium on said nickel layer, and a layer of gold on said palladium layer.

23. The method according to claim 18 wherein said metallurgical preparation comprises the steps of:
oxidizing said first surface of said base metal;
plating a silver layer on selected areas of said base metal oxide; and
plating on said second surface consecutively a layer of nickel on said base metal, a layer of palladium on said nickel layer, and a layer of gold on said palladium layer.

24. The method according to claim 23 wherein said step of oxidizing is provided by unaided metal oxide growth or by stimulated metal oxide growth.

25. The method according to claim 18 wherein said step of preparing said second surface metallurgically is performed on exposed base metal portions after semiconductor devices have been assembled and encapsulated on said leadframe, said metallurgical preparation comprising the steps of:
plating on said exposed portions consecutively a layer of nickel on said base metal, a layer of palladium on said nickel layer, and a layer of gold on said palladium layer.
